(19) United States
(12) Patent Application Publication
(10) Pub. No.: US 2025/0357244 A1
(43) Pub. Date: Nov. 20, 2025

(54) SEMICONDUCTOR PACKAGE

(71) Applicant: Samsung Electronics Co., Ltd., Suwon-si (KR)

(72) Inventors: Minwoo Cho, Suwon-si (KR); Shlege Lee, Suwon-si (KR)

(21) Appl. No.: 19/056,834

(22) Filed: Feb. 19, 2025

(30) Foreign Application Priority Data
May 17, 2024 (KR) 10-2024-0064215

(51) Int. Cl. H01L 23/367; H01L 23/00; H01L 23/373

(52) U.S. Cl. CPC H01L 23/3675; H01L 23/3736; H01L 24/32; H01L 2224/32245; H01L 2924/16235; H01L 2924/16251; H01L 2924/1632

(57) ABSTRACT

A semiconductor package may include a package substrate providing a mounting region and an edge region at least partially surrounding the mounting region, the edge region being spaced apart from the mounting region in a horizontal direction; a semiconductor device mounted on the mounting region; a heat slug provided on the package substrate and the semiconductor device to define an internal space between the package substrate and the heat slug, and the semiconductor device is provided in the internal space; and a plurality of heat dissipation fins provided on the heat slug, each of the plurality of heat dissipation fins arranged along the edge region of the package substrate and extending in a vertical direction, and each of the plurality of heat dissipation fins extends in the horizontal direction toward the semiconductor device.

### CROSS-REFERENCE TO RELATED APPLICATION

This application claims priority under 35 U.S.C. § 119 to Korean Patent Application No. 10-2024-0064215, filed on May 17, 2024, in the Korean Intellectual Property Office (KIPO), the contents of which are herein incorporated by reference in their entirety.

### BACKGROUND

The present disclosure relates to a semiconductor package, and more particularly, to a semiconductor package including a heat dissipation member to effectively dissipate heat therein.

A heat dissipation member may be applied for improving the heat performance of a semiconductor package and preventing warpage of the semiconductor package. When cooling a semiconductor package using a forced convection cooling method, it is necessary to increase a surface area of the semiconductor package exposed to the forced convection in order to effectively dissipate heat.

### SUMMARY

Embodiments of the present disclosure provide a semiconductor package capable of effectively dissipating heat therein.

According to some embodiments, a semiconductor package includes a package substrate including a mounting region and an edge region at least partially surrounding the mounting region, the edge region being spaced apart from the mounting region in a horizontal direction. The semiconductor package further includes a semiconductor device mounted on the mounting region and a heat slug provided on the package substrate and the semiconductor device to define an internal space between the package substrate and the heat slug, and the semiconductor device is provided in the internal space. The semiconductor package further includes a plurality of heat dissipation fins provided on the heat slug, each of the plurality of heat dissipation fins arranged along the edge region of the package substrate and extending in a vertical direction, and each of the plurality of heat dissipation fins extends in the horizontal direction toward the semiconductor device.

According to some embodiments of the present disclosure, a semiconductor package includes a package substrate including a mounting region and an edge region at least partially surrounding the mounting region, the edge region being spaced apart from the mounting region in a horizontal direction; a semiconductor device mounted on the mounting region of the package substrate; and a heat dissipation member at least partially covering the package substrate and the semiconductor device. The heat dissipation member includes a heat slug including a first portion provided on the semiconductor device, a second portion provided on the edge region of the package substrate, and a connecting portion connecting the first portion and the second portion; and a plurality of heat dissipation fins provided on the second portion of the heat slug, each of the plurality of heat dissipation fins arranged along the edge region of the package substrate and extending in a vertical direction.

According to some embodiments of the present disclosure, a semiconductor package includes a package substrate including a mounting region and an edge region surrounding the mounting region, the edge region being spaced apart from the mounting region in a horizontal direction; a semiconductor device mounted on the mounting region of the package substrate; a heat slug including a first portion provided on the semiconductor device, a second portion provided on the edge region of the package substrate, and a connecting portion connecting the first portion and the second portion; a plurality of heat dissipation fins provided on the second portion of the heat slug, each of the plurality of heat dissipation fins arranged along the edge region of the package substrate and extending in a vertical direction; and a thermal adhesive member including a first adhesive member provided between the semiconductor device and the first portion of the heat slug and a second adhesive member provided between the package substrate and the second portion of the heat slug. A first distance from an upper surface of the package substrate to an upper surface of each of the plurality of heat dissipation fins is less than a second distance from the upper surface of the package substrate to an upper surface of the first portion of the heat slug, and each of the plurality of heat dissipation fins extends in the horizontal direction toward the semiconductor device.

According to some embodiments of the present disclosure, a semiconductor package may include a package substrate, a semiconductor device, and a heat dissipation member at least partially covering the package substrate and the semiconductor device.

The heat dissipation member may include a heat slug provided on the package substrate and the semiconductor device, and a plurality of heat dissipation fins, each of the plurality of heat dissipation fins provided on the heat slug to be arranged along an edge region of the package substrate and extending in a vertical direction.

Accordingly, the plurality of heat dissipation fins may improve thermal performance of the semiconductor package by increasing a surface area exposed to forced convection. Furthermore, the plurality of heat dissipation fins may improve the thermal performance of the semiconductor package by increasing velocity of fluid passing between each of the plurality of heat dissipation fins. Thus, the plurality of heat dissipation fins may effectively reduce temperature of the semiconductor package.

### BRIEF DESCRIPTION OF THE DRAWINGS

FIG. 1 is a plan view illustrating a semiconductor package in accordance with some embodiments of the present disclosure.

FIG. 2 is a cross-sectional view taken along the line A-A′ in FIG. 1.

FIG. 3 is a cross-sectional view illustrating cooling the semiconductor package in FIG. 1.

FIG. 4 is a perspective view illustrating portion ‘M1’ in FIG. 3.

FIGS. 5 to 12 are views illustrating a method of manufacturing a semiconductor package in accordance with some embodiments of the present disclosure.

FIG. 13 is a plan view illustrating a semiconductor package in accordance with some embodiments of the present disclosure.

FIG. 14 is a cross-sectional view taken along the line D-D′ in FIG. 13.

FIG. 15 is a cross-sectional view illustrating a semiconductor package in accordance with some embodiments of the present disclosure.

FIG. 16 is a plan view illustrating the semiconductor package in FIG. 15.

FIG. 17 is a perspective view illustrating portion ‘M2’ in FIG. 15.

FIG. 18 is a cross-sectional view illustrating a semiconductor package in accordance with some embodiments of the present disclosure.

FIG. 19 is a perspective view illustrating portion ‘M3’ in FIG. 18.

FIG. 20 is a plan view illustrating a semiconductor package in accordance with some embodiments of the present disclosure.

FIG. 21 is a cross-sectional view taken along the line F-F′ in FIG. 20.

### DETAILED DESCRIPTION

Advantages and features of the present disclosure, and a method of achieving the advantages and features will become apparent with reference to embodiments described below in detail together with the accompanying drawings. However, the embodiments of the present disclosure are not limited to the example embodiments as disclosed herein, but may be implemented in various different forms. Thus, these embodiments are set forth only to make the present disclosure, and to inform the scope of the present disclosure to those of ordinary skill in the technical field to which the present disclosure belongs, and the present disclosure is only defined by the scope of the claims.

The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise. It will be further understood that the terms “comprise”, “comprising”, “include”, and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of associated listed items. Expression such as “at least one of” when preceding a list of elements may modify the entire list of elements and may not modify the individual elements of the list. In interpretation of numerical values, an error or tolerance therein may occur even when there is no explicit description thereof.

Spatially relative terms, such as “beneath,” “below,” “lower,” “under,” “above,” “upper,” and the like, may be used herein for ease of illustration to illustrate one element or feature's relationship to another element or feature as illustrated in the figures. It will be understood that the spatially relative terms are intended to encompass different orientations of the device in use or in operation, in addition to the orientation depicted in the figures. For example, when the device in the drawings may be turned over, elements described as “below” or “beneath” or “under” other elements or features would then be oriented “above” the other elements or features. Thus, the example terms “below” and “under” may encompass both an orientation of above and below. The device may be otherwise oriented, for example, rotated 90 degrees or at other orientations, and the spatially relative descriptors used herein should be interpreted accordingly.

It will be understood that, although the terms “first”, “second”, “third”, and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

Hereinafter, example embodiments of the present disclosure will be explained in detail with reference to the accompanying drawings.

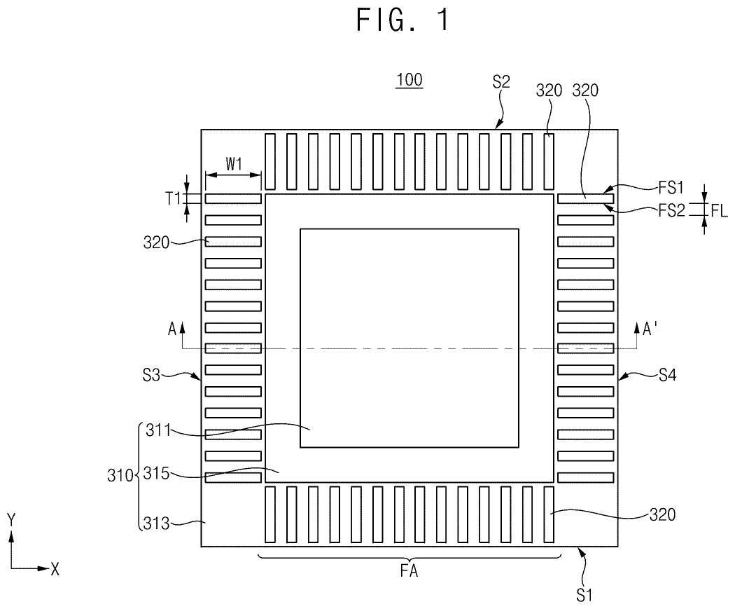

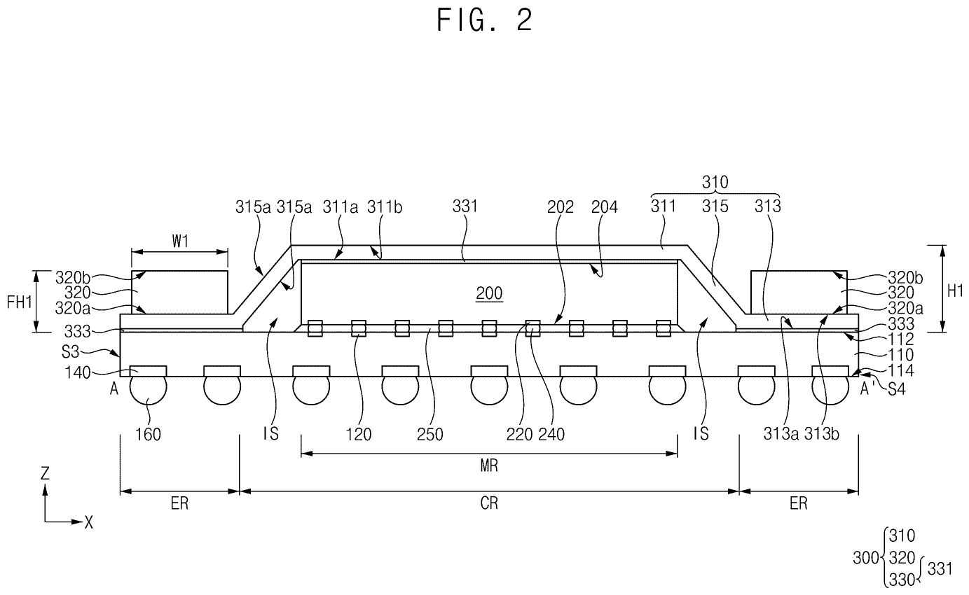

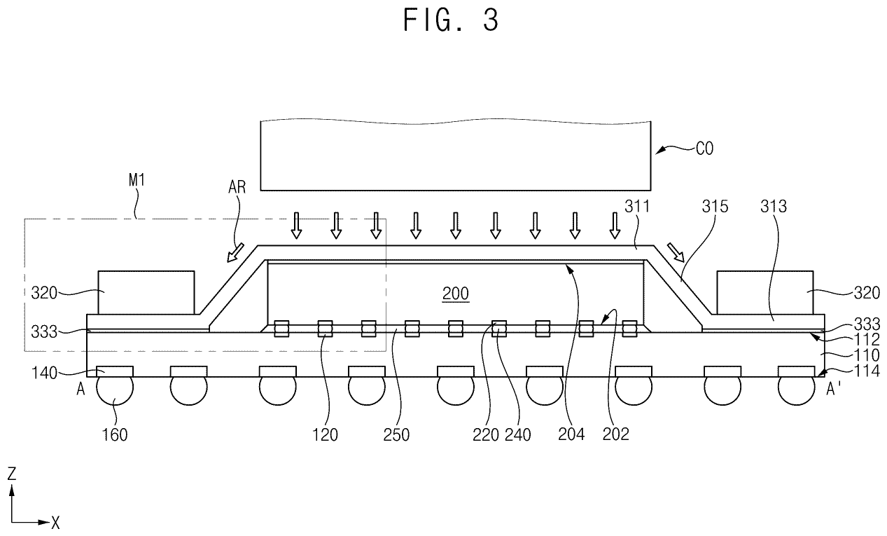

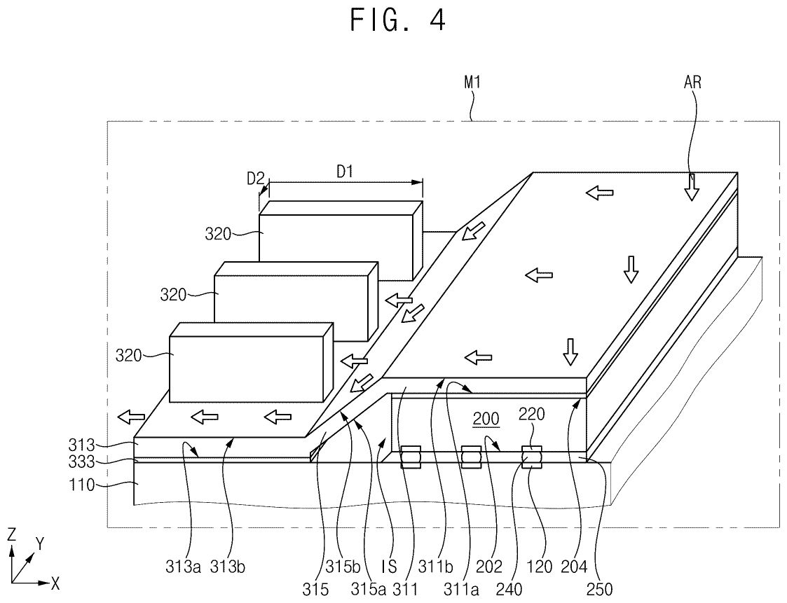

FIG. 1 is a plan view illustrating a semiconductor package in accordance with some embodiments. FIG. 2 is a cross-sectional view taken along the line A-A′ in FIG. 1. FIG. 3 is a cross-sectional view illustrating cooling the semiconductor package in FIG. 1. FIG. 4 is a perspective view illustrating portion ‘M1’ in FIG. 3.

Referring to FIGS. 1 to 4, a semiconductor package 100 may include a package substrate 110, a semiconductor device 200 mounted on the package substrate 110, and a heat dissipation member 300 at least partially covering the package substrate 110 and the semiconductor device 200.

In some embodiments, the package substrate 110 may have an upper surface 112 and a lower surface 114 that face each other. The package substrate 110 may include a plurality of first substrate pads 120 provided on the upper surface 112, a plurality of second substrate pads 140 provided on the lower surface 114, and a plurality of external connection members 160 provided on the plurality of second substrate pads 140. For example, in some embodiments, the plurality of first substrate pads 120, the plurality of second substrate pads 140, and the plurality of external connection members 160 may include a conductive metallic material.

The package substrate 110 may include a middle portion CR provided in a middle portion thereof and an edge region ER surrounding the middle portion CR.

The middle portion CR of the package substrate 110 may include a mounting region MR. The plurality of first substrate pads 120 may be disposed on the mounting region MR such that at least a portion of each of the plurality of first substrate pads 120 is exposed from the upper surface 112. For example, in some embodiments, the mounting region MR may have a rectangular shape when viewed in a plan view. The mounting region MR may be a region configured to mount the semiconductor device 200 as will be described later.

The edge region ER of the package substrate 110 may be spaced apart from the mounting region MR in a horizontal direction (X or Y direction) to surround the mounting region MR. For example, as shown in FIG. 1, the package substrate 110 may include a first side portion S1 and a second side portion S2 extending in a first horizontal direction (X direction) to face each other. Further, as shown in FIG. 1, the package substrate 110 may include a third side portion S3 and a fourth side portion S4 extending in a second horizontal direction (Y direction) perpendicular to the first horizontal direction (X direction) to face each other. The edge regions ER may be arranged to surround the mounting region MR along the first to fourth side portions S1, S2, S3, and S4 of the package substrate 110.

Although internal wiring is not illustrated in the figures, the package substrate 110 may include a plurality of internal wiring. The internal wiring may be provided within the package substrate 110 to electrically connect the plurality of first substrate pads 120, the plurality of second substrate pads 140, and the plurality of external connection members 160.

While only a few substrate pads 120, 140 are illustrated in the figures, it will be understood that the number, shape, and arrangement of the substrate pads 120, 140 are provided as an example so the present disclosure is not limited thereto.

In some embodiments, the semiconductor device 200 may include a front surface 202 and a backside surface 204 facing each other, and the semiconductor device 200 may be mounted on the mounting region MR of the package substrate 110 such that the front surface 202 faces the package substrate 110. For example, in some embodiments, the front surface 202 may be an active surface, on which a plurality of electronic elements are formed, and the backside surface 204 may be an inactive surface.

The semiconductor device 200 may be a single semiconductor chip or a semiconductor package including a plurality of semiconductor chips. For example, in some embodiments, the semiconductor chip may include a logic chip having a logic circuit. Alternatively, in some embodiments, the semiconductor chip may include a volatile memory device, such as DRAM, or a non-volatile memory device, such as NAND flash memory.

The semiconductor device 200 may include a plurality of chip pads 220 provided on the front surface 202, a plurality of conductive connection members 240 provided on each of the plurality of chip pads 220, and an underfill member 250 provided on the front surface 202 to at least partially cover the plurality of conductive connection members 240. For example, in some embodiments, the plurality of chip pads 220 and the plurality of conductive connection members 240 may include a conductive metallic material.

The semiconductor device 200 may be mounted on the package substrate 110 in a flip-chip method. For example, in some embodiments, the semiconductor device 200 may be mounted on the package substrate 110 via the plurality of conductive connection members 240 that are respectively provided between the plurality of first substrate pads 120 and the plurality of chip pads 220.

The underfill member 250 may be provided on the mounting region MR of the package substrate 110 to fill a gap between the package substrate 110 and the semiconductor device 200. The underfill member 250 may fill the gap between the upper surface 112 of the package substrate 110 and the front surface 202 of the semiconductor device 200 to respectively cover the plurality of conductive connection members 240. For example, in some embodiments, the underfill member 250 may be a material having relatively high fluidity to effectively cover the gap between the package substrate 110 and the semiconductor device 200. The underfill member 250 may include an epoxy material.

While only a few chip pads 220 are illustrated in the figures, it will be understood that the number, shape, and arrangement of the chip pads 220 are provided as an example, so the present disclosure is not limited thereto.

In some embodiments, the heat dissipation member 300 may include a heat slug 310 provided on the semiconductor device 200 and the package substrate 110, and a plurality of first heat dissipation fins 320 provided on the heat slug 310. Additionally, the heat dissipation member 300 may further include a thermal adhesive member 330 provided below the heat slug 310. The heat dissipation member 300 may be a structure for effectively dissipating heat generated from the semiconductor device 200 to the outside thereof, thereby decreasing temperature of the semiconductor package 100. The heat dissipation member 300 may include a metallic material having a high thermal conductivity. For example, in some embodiments, the heat dissipation member 300 may include a metallic material such as copper (Cu), aluminum (Al), or the like. The heat slug 310 and the plurality of first heat dissipation fins 320 may include the same metallic material. Alternatively, the heat slug 310 and the plurality of first heat dissipation fins 320 may include different metallic materials.

The heat slug 310 may include a first portion 311 provided on the semiconductor device 200, a second portion 313 provided on the edge region ER of the package substrate 110, and a connecting portion 315 connecting the first portion 311 and the second portion 313. The heat slug 310 may effectively dissipate heat generated by the semiconductor device 200 or the like to the outside thereof, thereby decreasing the temperature of the semiconductor package 100. Further, the heat slug 310 may physically protect the semiconductor device 200 and reduce warpage of the semiconductor package 100. For example, in some embodiments, the heat slug 310 may include a metallic material such as copper (Cu), aluminum (Al), or the like.

The first portion 311 of the heat slug 310 may include a first surface 311a and a second surface 311b facing each other. The first surface 311a of the first portion 311 may be a surface facing a semiconductor device 200. The second surface 311b of the first portion 311 may be an exposed surface that is exposed to the outside of the semiconductor package 100. The first portion 311 of the heat slug 310 may have a shape corresponding to the backside surface 204 of the semiconductor device 200. For example, in some embodiments, the first portion 311 of the heat slug 310 may have a square shape or a rectangular shape when viewed in a plan view.

The heat slug 310 may have a first height H1 in the vertical direction (Z direction). For example, in some embodiments, the first height H1 of the heat slug 310 may be a height from the upper surface 112 of the package substrate 110 to the second surface 311b of the first portion 311 of the heat slug 310.

The second portion 313 of the heat slug 310 may include a first surface 313a and a second surface 313b facing each other. The first surface 313a of the second portion 313 may be a surface that is in contact with the package substrate 110. The second surface 313b of the second portion 313 of the heat slug 310 may be an exposed surface that is exposed to the outside of the semiconductor package 100. The second portion 313 of the heat slug 310 may be spaced apart from the semiconductor device 200 in the horizontal direction (X or Y direction), and the second portion 313 of the heat slug 310 may be provided along a plurality of side portions S1, S2, S3, S4 of the package substrate 110 to surround the semiconductor device 200.

The connecting portion 315 of the heat slug 310 may have a first inclined surface 315a and a second inclined surface 315b facing each other. The first inclined surface 315a of the connecting portion 315 may be a surface facing the package substrate 110. The second inclined surface 315b of the connecting portion 315 may be a surface exposed to the outside of the semiconductor package 100. The connecting portion 315 may extend from one end portion of the first portion 311 of the heat slug 310 to one end portion of the second portion 313 of the heat slug 310 to connect the first portion 311 and the second portion 313.

The heat slug 310 may be provided on the package substrate 110 and the semiconductor device 200 to define an internal space IS between the package substrate 110 and the heat slug 310. The internal space IS may be a space in which the semiconductor device 200 is housed. For example, in some embodiments, the internal space IS may be defined by the upper surface 112 of the package substrate 110, the first surface 311a of the first portion 311 of the heat slug 310, and the first inclined surface 315a of the connecting portion 315 of the heat slug 310.

The first portion 311, the second portion 313, and the connecting portion 315 of the heat slug 310 may be provided on the package substrate 110 to at least partially cover the package substrate 110 and the semiconductor device 200. Accordingly, in some embodiments, the heat slug 310 may physically protect the semiconductor device 200 by sealing the internal space IS from the outside of the semiconductor package 100.

The plurality of first heat dissipation fins 320 may be provided on the second portion 313 of the heat slug 310. For example, in some embodiments, the plurality of first heat dissipation fins 320 may be provided on the second portion 313 of the heat slug 310 within the edge region ER of the package substrate 110 to be arranged along the plurality of side portions S1, S2, S3, S4 of the package substrate 110. The plurality of first heat dissipation fins 320 may be structures to increase the surface area of the heat dissipation member 300, thereby increasing the heat dissipated through the heat dissipation member 300 and reducing the temperature of the semiconductor package 100. For example, in some embodiments, the plurality of first heat dissipation fins 320 may include a metallic material with high thermal conductivity, such as copper (Cu), aluminum (Al), or the like.

Each of the plurality of first heat dissipation fins 320 may have a first surface 320a that is in contact with the second portion 313 of the heat slug 310 and a second surface 320b opposite to the first surface 320a and exposed to the outside of the semiconductor package 100.

Each of the plurality of first heat dissipation fins 320 may extend in the vertical direction (Z direction). As shown in FIG. 2, each of the plurality of first heat dissipation fins 320 may have a first fin height FH1 in the vertical direction (Z direction). For example, the first fin height FH1 may be a height from the upper surface 112 of the package substrate 110 to the second surface 320b of each of the plurality of first heat dissipation fins 320.

The first fin height FH1 of each of the plurality of first heat dissipation fins 320 may be less than the first height H1 of the heat slug 310. Thus, the height in the vertical direction of the semiconductor package 100 may remain constant regardless of the first fin height FH1 of the plurality of first heat dissipation fins 320.

Each of the plurality of first heat dissipation fins 320 may extend in a first direction D1 toward the semiconductor device 200. For example, each of the plurality of first heat dissipation fins 320 may extend from the plurality of side portions S1, S2, S3, S4 of the package substrate 110 toward the semiconductor device 200.

Each of the plurality of first heat dissipation fins 320 may be spaced apart from each other in a second direction D2 perpendicular to the first direction D1. For example, as shown in FIG. 1, in some embodiments, each of the plurality of first heat dissipation fins 320 may have a first side surface FS1 and a second side surface FS2 extending in the first direction D1 to face each other. Each of the plurality of first heat dissipation fins 320 adjacent to each other may have a first spacing distance FL in the second direction D2.

Each of the plurality of first heat dissipation fins 320 may have a first width W1 extending in the first direction D1 and a first thickness T1 extending in the second direction D2. The first width W1 may be greater than the first thickness T1. For example, in some embodiments, each of the plurality of first heat dissipation fins 320 may have a square shape when viewed in a plan view.

While only a few of the plurality of first heat dissipation fins 320 are illustrated in the figures, it will be understood that the number, shape and arrangement of the plurality of first heat dissipation fins 320 are provided as an example, so the present disclosure is not limited thereto.

The thermal adhesive member 330 may include a first adhesive member 331 provided between the semiconductor device 200 and the first portion 311 of the heat slug 310, and a second adhesive member 333 provided between the package substrate 110 and the second portion 313 of the heat slug 310. For example, in some embodiments, the first adhesive member 331 may be provided between the backside surface 204 of the semiconductor device 200 and the first surface 311a of the first portion 311 of the heat slug 310 to sufficiently fill a space between the semiconductor device 200 and the first portion 311 of the heat slug 310. Further, in some embodiments, the second adhesive member 333 may be provided between the upper surface 112 of the package substrate 110 and the first surface 313a of the second portion 313 of the heat slug 310 to sufficiently fill a space between the package substrate 110 and the second portion 313 of the heat slug 310.

The thermal adhesive member 330 may include a thermal interface material. The thermal interface material may be a material for enhancing thermal conductivity between two contact surfaces by facilitating heat transfer. Specifically, the thermal interface material may be a structure for effectively transferring heat between components by closely fitting the components so that there are no microscopic spaces between components. Alternatively, the thermal adhesive member 330 may include a variety of adhesive materials such as adhesive films, pads, greases, gels, and the like.

Referring again to FIGS. 3 and 4, air AR may be introduced onto the semiconductor package 100 using a cooling apparatus CO to increase heat dissipation through the heat dissipation member 300, thereby reducing the temperature of the semiconductor package 100. For example, in some embodiments, the cooling apparatus CO may be an apparatus that injects air AR into the semiconductor package 100 to generate forced convection, thereby reducing the temperature of the semiconductor package 100. In some embodiments, the cooling apparatus CO may include a fan.

For example, in some embodiments, air AR introduced from the cooling apparatus CO may move along the first portion 311 and the connecting portion 315 of the heat slug 310 to reach the second portion 313 of the heat slug 310 and the plurality of first heat dissipation fins 320. The air AR may then pass between each of the plurality of first heat dissipation fins 320 to effectively dissipate heat generated by the semiconductor package 100.

For example, in some embodiments, the plurality of first heat dissipation fins 320 may increase a contact region between the air AR and the semiconductor package 100. The plurality of first heat dissipation fins 320 may increase the surface area of the semiconductor package 100 exposed to forced convection, thereby improving the thermal performance of the semiconductor package 100.

Further, the plurality of first heat dissipation fins 320 may increase a flow rate of the air AR passing between the plurality of first heat dissipation fins 320. As the flow rate of air AR increases, the heat dissipated through the plurality of first heat dissipation fins 320 may increase, thereby improving the thermal performance of the semiconductor package 100.

Thus, the plurality of first heat dissipation fins 320 may effectively improve the thermal performance of the semiconductor package 100, thereby effectively reducing the temperature of the semiconductor package 100.

Further, the number of the plurality of first heat dissipation fins 320 may be determined by considering the thermal performance of the semiconductor package 100.

For example, in some embodiments, each of the plurality of first heat dissipation fins 320 may include a plurality of fin arrays FA respectively disposed on the edge regions ER of the package substrate 110 and adjacent to the plurality of side portions S1, S2, S3, and S4. As the number of the first heat dissipation fins 320 included in the fin array FA increases, the surface area exposed to forced convection may increase, thereby effectively dissipating heat from the semiconductor package 100. Furthermore, as the number of the first heat dissipation fins 320 included in the fin array FA may increase, the spacing distance between the first heat dissipation fins 320 may decrease, thereby increasing the velocity of fluid passing between the first heat dissipation fins 320 and effectively dissipating heat of the semiconductor package 100. Thus, as the number of the first heat dissipation fins 320 increases, the temperature of the semiconductor package 100 may be effectively reduced. However, as the number of the first heat dissipation fins 320 increases, the flow rate of the fluid passing between the first heat dissipation fins 320 may decrease, so the heat dissipated may reach a saturation state. Therefore, when the number of the first heat dissipation fins 320 is within a certain range, the temperature of the semiconductor package 100 may remain constant without further decreasing even when the number of the first heat dissipation fins 320 is increased.

TABLE 1

| | Simulation | Simulation | Simulation |
|---|---|---|---|
| | Result 1 | Result 2 | Result 3 |
| Number of the heat | 12 | 14 | 16 |
| dissipation fins | | | |
| Spacing distance | 3.5 | 2.9 | 2.5 |
| between each of the heat | | | |
| dissipation fins (mm) | | | |
| Maximum velocity | 20.8 | 23.6 | 26.7 |
| of the fluid (m/s) | | | |
| Temperature of the | 103 | 97.5 | 97.5 |
| semiconductor | | | |
| package (° C.) | | | |

Table 1 illustrates simulation results measuring the temperature of a semiconductor package 100 while varying the number of the plurality of first heat dissipation fins 320.

In Table 1, the “number of the plurality of heat dissipation fins” may refer to the number of heat dissipation fins 320 arranged along a side portion S1, S2, S3, S4 of the semiconductor package 100. For example, the same number of heat dissipation fins 320 may be disposed along each of the side portions S1, S2, S3, S4 of the semiconductor package 100. Further, the “spacing distance between the heat dissipation fins” may refer to a spacing distance between adjacent heat dissipation fins 320. For example, as the number of the plurality of heat dissipation fins increases, the spacing distance between the heat dissipation fins may decrease. Further, the “maximum flow velocity” may refer to a velocity of the fastest portion of the air flowing along a surface of the semiconductor package 100. For example, the maximum flow velocity may be the velocity of the air passing between the heat dissipation fins 320.

For example, conditions of the simulation may be as follows.

A simulation may be performed in which a fan is positioned above the semiconductor package 100, and air AR is injected onto the semiconductor package 100 through the fan. In this case, a flow rate of the air AR injected from the fan may be about 3 m/s. Further, the plurality of first heat dissipation fins 320 may have a first length in a first horizontal direction (e.g., X direction) facing the semiconductor device 200, a second length in a second horizontal direction (e.g., Y direction) perpendicular to the first horizontal direction (X direction), and a third length in a vertical direction (e.g., Z direction). In this case, the first length may be about 4.2 mm, and the second length may be about 2 mm, and the third length may be about 1.2 mm.

For example, the results of the simulation may be as follows.

Referring again to Table 1, as the number of the plurality of heat dissipation fins 320 increases, the surface area of the semiconductor package 100 in contact with air AR may increase, thereby reducing the temperature of the semiconductor package 100. However, if the number of the plurality of heat dissipation fins 320 exceeds a certain range, the air flow rate between the plurality of heat dissipation fins 320 may decrease so that the temperature of the semiconductor package 100 may remain constant.

For example, in some embodiments, the number of the plurality of heat dissipation fins may be within a range of between 12 to 16. Specifically, in case that the number of the plurality of heat dissipation fins 320 is 12, the temperature of the semiconductor package 100 may be about 103° C. Further, in case that the number of the plurality of heat dissipation fins is 14, the temperature of the semiconductor package 100 may be about 97.5° C. Further, in case that the number of the plurality of heat dissipation fins is 16, the temperature of the semiconductor package 100 may be about 97.5° C. Thus, in some embodiments, the number of the plurality of heat dissipation fins may be determined as a minimum number at which the temperature of the semiconductor package 100 is saturated. However, it will be understood that this is provided as an example, so the present disclosure is not limited thereto. Therefore, in some embodiments, the number of the plurality of heat dissipation fins and the temperature of the semiconductor package 100 may vary.

As described above, in some embodiments, the semiconductor package 100 may include a package substrate 110, a semiconductor device 200 mounted on the package substrate 110, and a heat dissipation member 300 at least partially covering the package substrate 110 and the semiconductor device 200.

The heat dissipation member 300 may include a heat slug 310 provided on the package substrate 110 and the semiconductor device 200, and the plurality of first heat dissipation fins 320 provided on the heat slug 310 respectively extending in a vertical direction (Z direction) to be arranged along the edge region ER of the package substrate 110.

Accordingly, in some embodiments, the plurality of first heat dissipation fins 320 may help to improve the thermal performance of the semiconductor package 100 by increasing the surface area of the semiconductor package 100 exposed to forced convection. Further, in some embodiments, the plurality of first heat dissipation fins 320 may help to improve the thermal performance of the semiconductor package 100 by increasing the velocity of fluid passing between the plurality of first heat dissipation fins 320. Thus, the plurality of first heat dissipation fins 320 may effectively reduce the temperature of the semiconductor package 100.

Hereinafter, a method of manufacturing the semiconductor package 100 in FIG. 1 will be described.

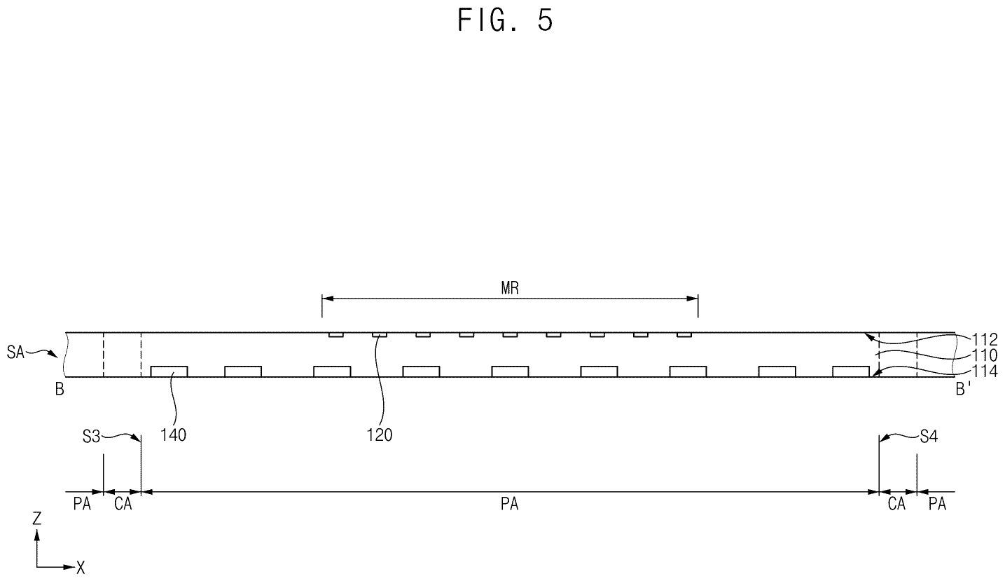

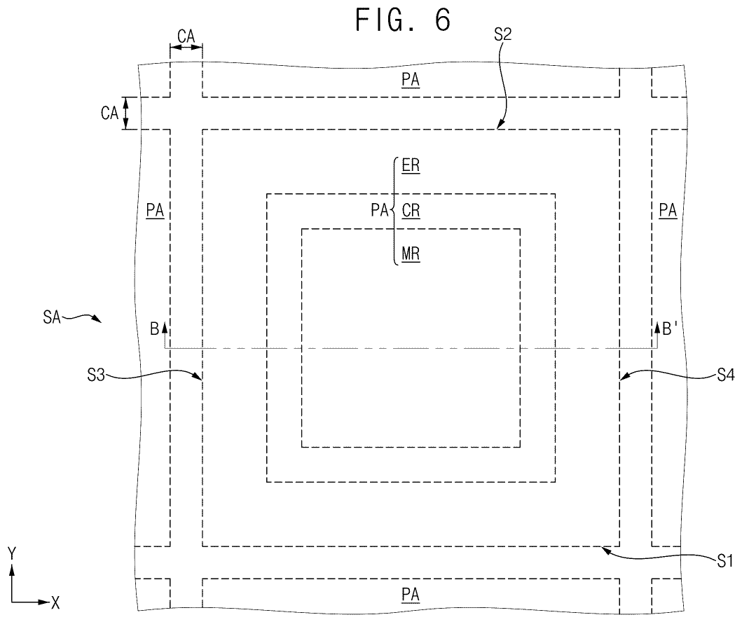

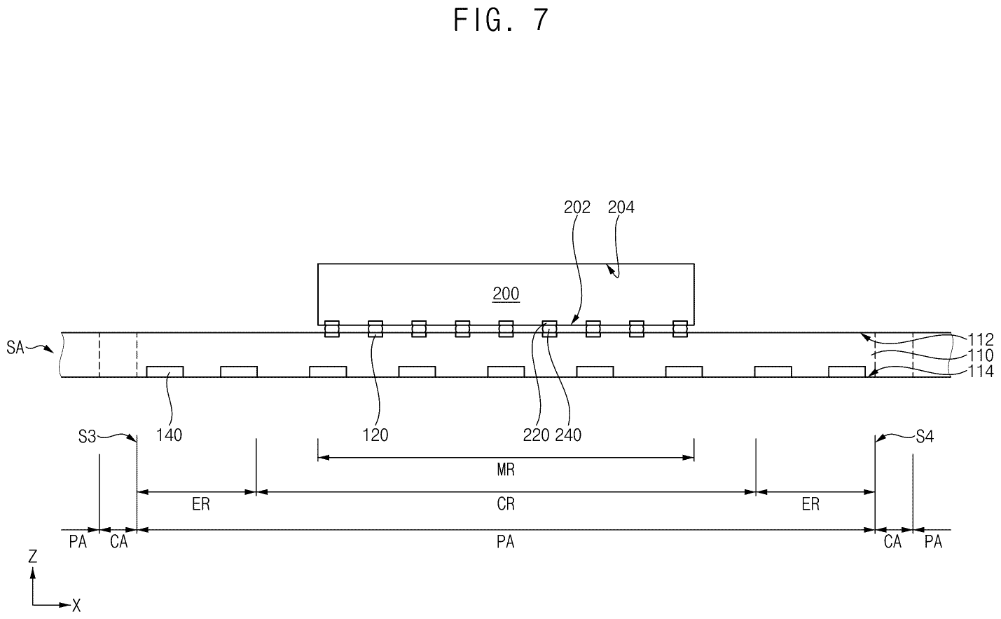

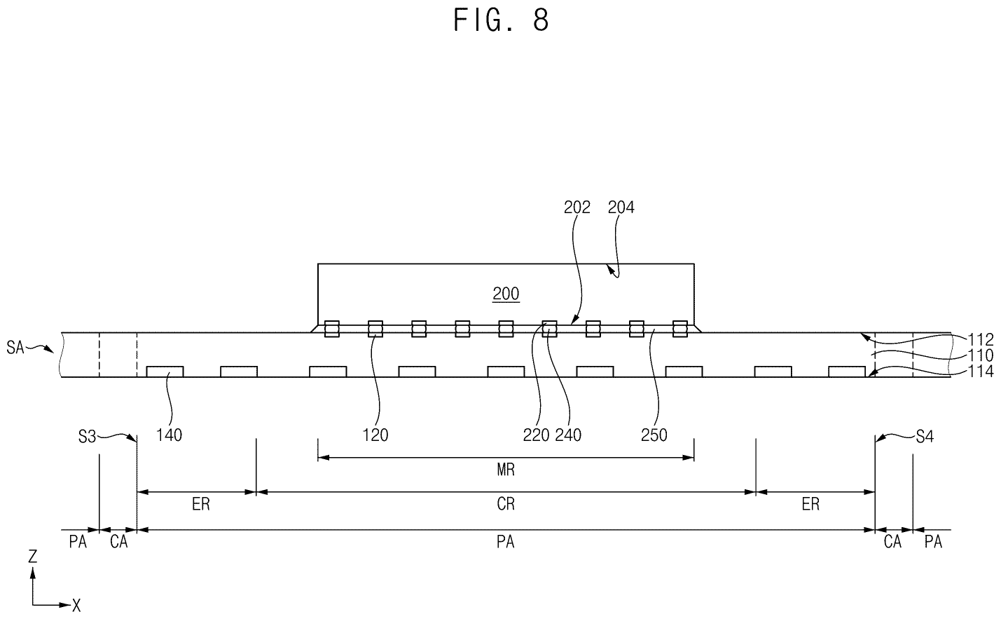

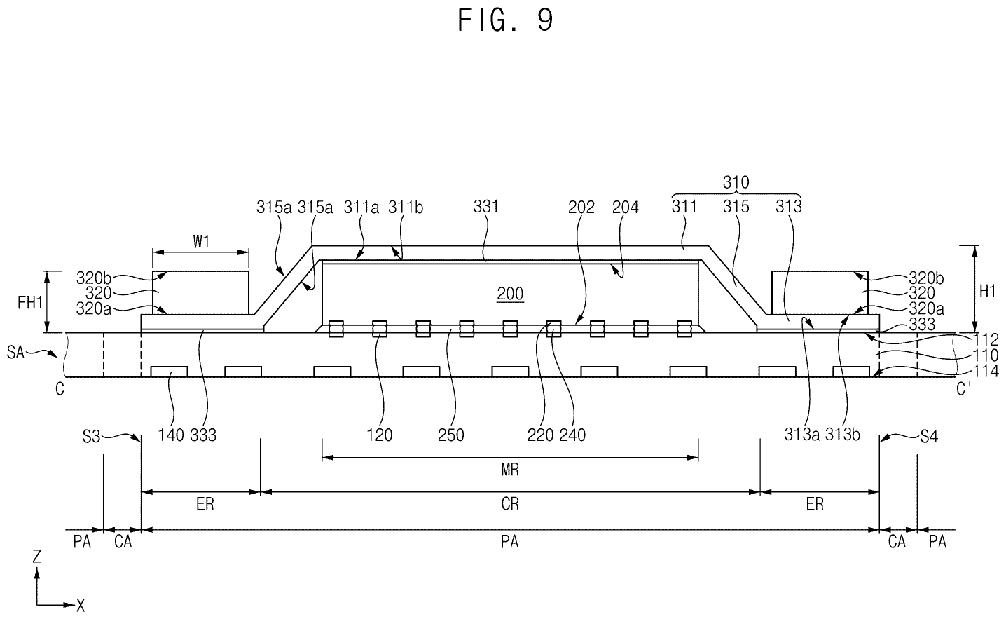

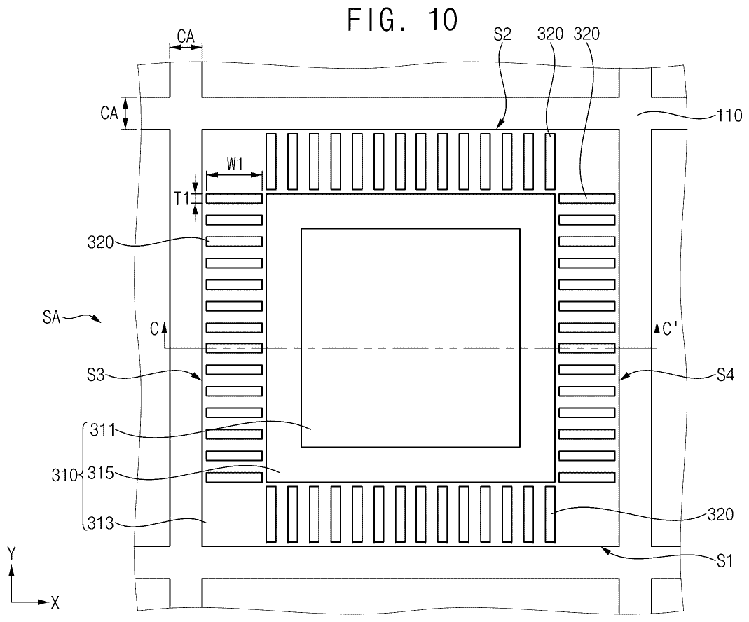

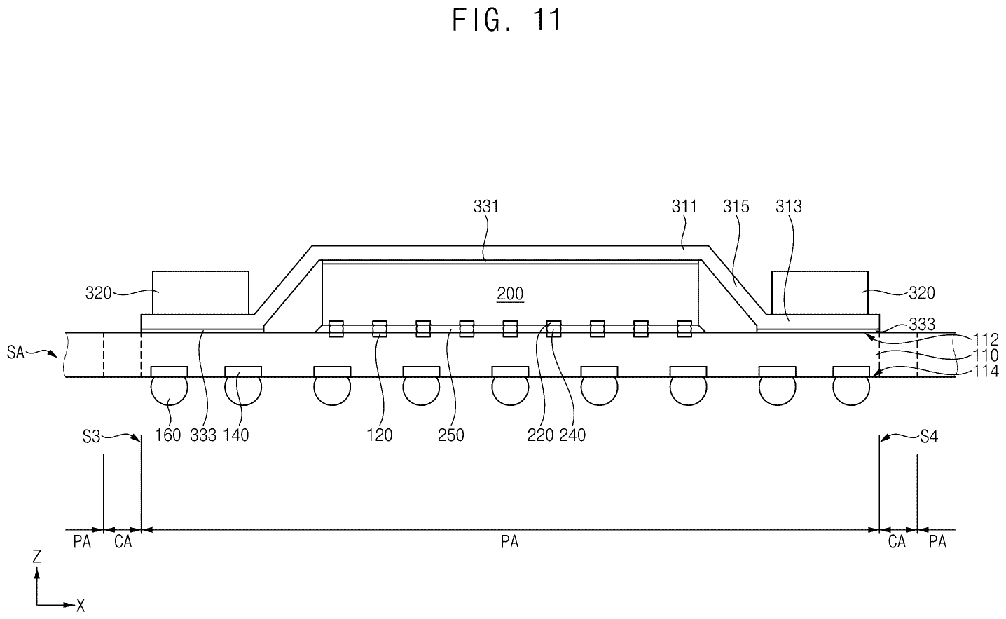

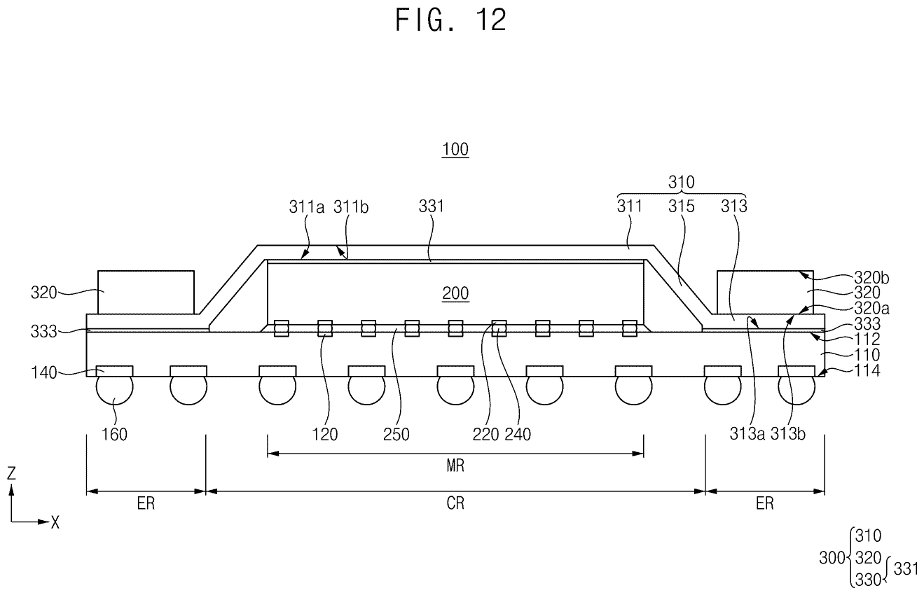

FIG. 5 is a cross-sectional view illustrating a substrate array. FIG. 6 is a plan view illustrating the substrate array of FIG. 5. FIG. 6 is a cross-sectional view taken along line B-B′ in FIG. 5. FIG. 7 is a cross-sectional view illustrating a semiconductor device mounted on the substrate array of FIG. 5. FIG. 8 is a cross-sectional view illustrating an underfill member injected on the substrate array of FIG. 7. FIG. 9 is a cross-sectional view illustrating a heat dissipation member attached to the substrate array of FIG. 8. FIG. 10 is a plan view illustrating the substrate array of FIG. 9. FIG. 10 is a cross-sectional view taken along line C-C′ in FIG. 9. FIG. 11 is a cross-sectional view illustrating a plurality of external connection members attached to the substrate array of FIG. 9. FIG. 12 is a cross-sectional view illustrating the substrate array of FIG. 11 cut along the cutting region.

Since the semiconductor package 100 manufactured by the manufacturing process described in FIGS. 5 to 12 is substantially identical to the semiconductor package 100 described in FIGS. 1 to 4, as such, identical components are denoted by the same reference numerals, and repeated descriptions of identical components may be omitted below.

Referring to FIGS. 5 and 6, a substrate array SA may be provided. As shown in FIGS. 5 and 6, in some embodiments, the substrate array SA may include a plurality of package regions PA, which respectively include a mounting region MR at a center portion, and a cutting region CA at least partially surrounding the plurality of package regions PA. The package regions PA may be regions in which a semiconductor package 100 is formed by processes as will be described later. Further, the cutting region CA may be a region to be removed to individualize the semiconductor package 100 by the processes as will be described later.

Referring to FIG. 7, a plurality of semiconductor devices including a semiconductor device 200 may each be mounted on a mounting region MR of the substrate array SA. The semiconductor device 200 may have a front surface 202 and a backside surface 204 facing each other. The front surface 202 may be an active surface on which a plurality of electronic elements are formed, and the backside surface 204 may be an inactive surface.

The semiconductor device 200 may be mounted such that the front surface 202 faces the substrate array SA. For example, in some embodiments, the semiconductor device 200 may be mounted on the package substrate 110 in a flip-chip method. For example, in some embodiments, the semiconductor device 200 may be mounted on the package substrate 110 via a plurality of conductive connection members 240 respectively provided between the plurality of first substrate pads 120 and the plurality of chip pads 220.

Referring to FIG. 8, an underfill material may be injected between the substrate array SA and the semiconductor device 200 to form an underfill member 250 that is disposed within the mounting region MR to at least partially cover the plurality of conductive connection members 240. For example, in some embodiments, the underfill material may be a material that is sufficiently fluid to at least partially cover a space between the package substrate 110 and the semiconductor device 200. The underfill material may include epoxy material.

Referring to FIGS. 9 and 10, a heat dissipation member 300 including a plurality of first heat dissipation fins 320 may be provided. The heat dissipation member 300 may be attached to the substrate array SA and the semiconductor device 200 by a thermal adhesive member 330.

For example, in some embodiments, the heat slug 310 and the plurality of first heat dissipation fins 320 of the heat dissipation member 300 may be integrally manufactured by using a molding process. In this case, the heat slug 310 and the plurality of first heat dissipation fins 320 may include the same metallic material. Alternatively, the plurality of first heat dissipation fins 320 may be attached to a second portion 313 of the heat slug 310. In this case, the heat slug 310 and the plurality of first heat dissipation fins 320 may include different metallic materials.

For example, in some embodiments, the heat dissipation member 300 may be secured to the substrate array SA and the semiconductor device 200 via a first adhesive member 331 provided between the first portion 311 of the heat slug 310 and the semiconductor device 200 and via a second adhesive member 333 provided between the second portion 313 of the heat slug 310 and the substrate array SA.

Accordingly, the first portion 311 of the heat slug 310 may be located above the semiconductor device 200 (e.g., in the Z direction), and the second portion 313 of the heat slug 310 and the plurality of first heat dissipation fins 320 may be located within the edge region ER of the substrate array SA.

Referring to FIG. 11, a plurality of external connection members 160 may be attached to a plurality of second substrate pads 140 respectively exposed from the lower surface 114 of the substrate array SA.

Referring to FIG. 12, the cutting regions CA of the substrate array SA may be removed by a cutting process to individualize the semiconductor package 100, which is formed on the package regions PA, thereby completing the semiconductor package 100.

However, while the figures illustrate that the semiconductor device 200 and the heat dissipation member 300 are mounted on the substrate array SA including a plurality of package regions PA and cutting regions CA, it will be appreciated that the present disclosure is not limited thereto. Accordingly, the semiconductor device 200 and the heat dissipation member 300 may be manufactured in such a manner that the semiconductor device 200 and the heat dissipation member 300 are mounted on an already individualized package substrate 110.

Hereinafter, another semiconductor package 101 in accordance with some embodiments of the present disclosure will be described.

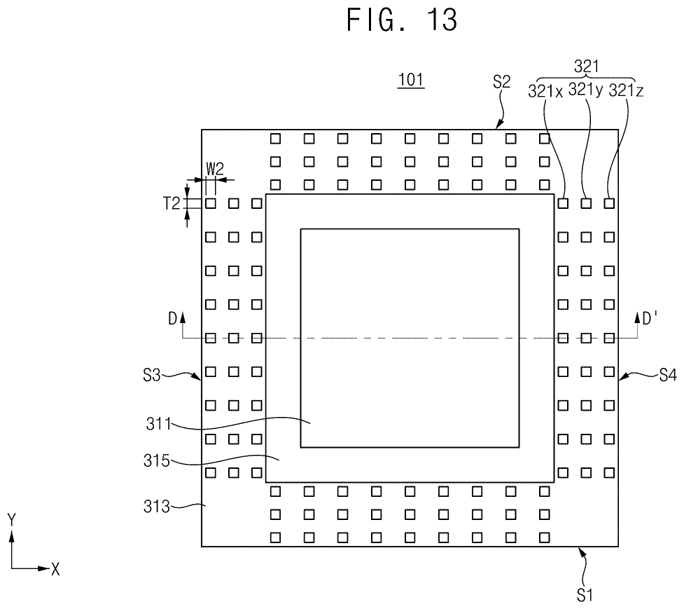

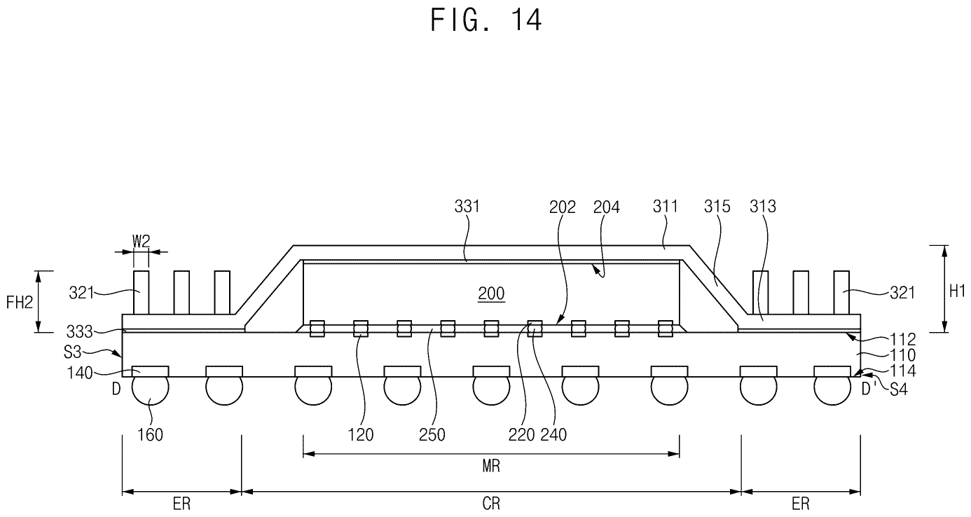

FIG. 13 is a plan view illustrating a semiconductor package 101 in accordance with some embodiments. FIG. 14 is a cross-sectional view taken along the line D-D′ in FIG. 13.

The semiconductor package 101 described in FIGS. 13 and 14 is substantially identical to the semiconductor package 100 described in FIGS. 1 to 4 except for the plurality of second heat dissipation fins 321, as such, identical components are denoted by the same reference numerals and repeated descriptions of identical components may be omitted below.

Referring to FIGS. 13 and 14, in some embodiments, the semiconductor package 101 may include a package substrate 110, a semiconductor device 200 mounted on the package substrate 110, and a heat dissipation member 300 at least partially covering the package substrate 110 and the semiconductor device 200.

In some embodiments, a plurality of second heat dissipation fins 321 may be provided on the second portion 313 of the heat slug 310. For example, in some embodiments, the plurality of second heat dissipation fins 321 may be provided on the second portion 313 of the heat slug 310 within an edge region ER of the package substrate 110 such that the plurality of second heat dissipation fins 321 are disposed along the plurality of side portions S1, S2, S3, S4 of the package substrate 110. For example, in some embodiments, the plurality of second heat dissipation fins 321 may include a metallic material having high thermal conductivity such as copper (Cu), aluminum (Al), or the like.

Each of the plurality of second heat dissipation fins 321 may be disposed on the second portion 313 of the heat slug 310 along the plurality of side portions S1, S2, S3, S4 of the package substrate 110. For example, in some embodiments, the first horizontal direction (X direction) may be a direction from the plurality of side portions S1, S2, S3, S4 of the package substrate 110 toward the semiconductor device 200. The second horizontal direction (Y direction) may be a direction perpendicular to the first horizontal direction and parallel to a side portion of the package substrate 110. Each of the plurality of second heat dissipation fins 321 may be disposed on the second portion 313 of the heat slug 310 to be spaced apart from each other in the second horizontal direction.

The plurality of second heat dissipation fins 321 may include first, second, and third heat dissipation sub-fins 321x, 321y, and 321z sequentially disposed in the first horizontal direction. For example, in some embodiments, the first to third heat dissipation sub-fins 321x, 321y, and 321z may be provided within the edge region ER of the package substrate 110 to be spaced apart from each other in the first horizontal direction. Accordingly, the plurality of second heat dissipation fins 321 may be disposed within the edge region ER to be arranged as an array form including a plurality of columns and rows.

Accordingly, in some embodiments, each of the plurality of second heat dissipation fins 321 may include heat dissipation sub-fins 321x, 321y, 321z, which may improve the thermal performance of the semiconductor package 101 by increasing surface area of the semiconductor package 101 exposed to forced convection. Thus, the plurality of second heat dissipation fins 321 may effectively reduce the temperature of the semiconductor package 101.

The heat dissipation sub-fins 321x, 321y, 321z may have a second width W2, which is an extension length in the first horizontal direction, and a second thickness T2, which is an extension length in the second horizontal direction. The second width W2 and the second thickness T2 may be the same. For example, in some embodiments, the heat dissipation sub-fins 321x, 321y, 321z may have a square shape when viewed in a plan view. Alternatively, in some embodiments, the heat dissipation sub-fins 321x, 321y, 321z may have a circular shape when viewed in a plan view.

Each of the plurality of second heat dissipation fins 321 may extend in a vertical direction (Z direction). Each of the plurality of second heat dissipation fins 321 may have a second fin height FH2 in the vertical direction (Z direction). For example, in some embodiments, the second fin height FH2 may be a height from the upper surface 112 of the package substrate 110 to an upper surface of each of the plurality of second heat dissipation fins 321. The second fin height FH2 of each of the plurality of second heat dissipation fins 321 may be less than the first height H1 of the heat slug 310. Thus, the height in the vertical direction of the semiconductor package 101 may remain constant regardless of the second fin height FH2 of the plurality of second heat dissipation fins 321.

While only a few of the plurality of second heat dissipation fins 321 and heat dissipation sub-fins 321x, 321y, 321z are illustrated in the figures, it will be understood that the number, shape, and arrangement of the plurality of second heat dissipation fins 321 and heat dissipation sub-fins 321x, 321y, 321z are provided as an example, so the present disclosure is not limited thereto.

Hereinafter, another semiconductor package 102 in accordance with some embodiments of the present disclosure will be described.

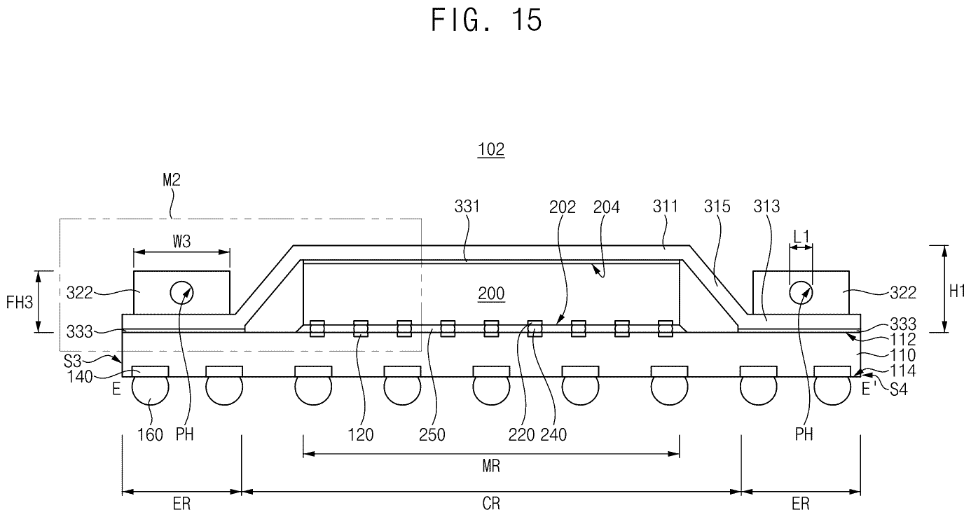

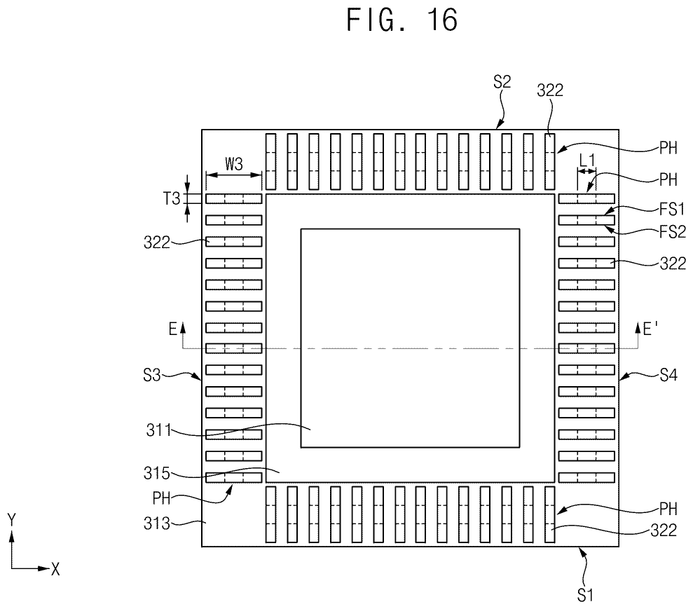

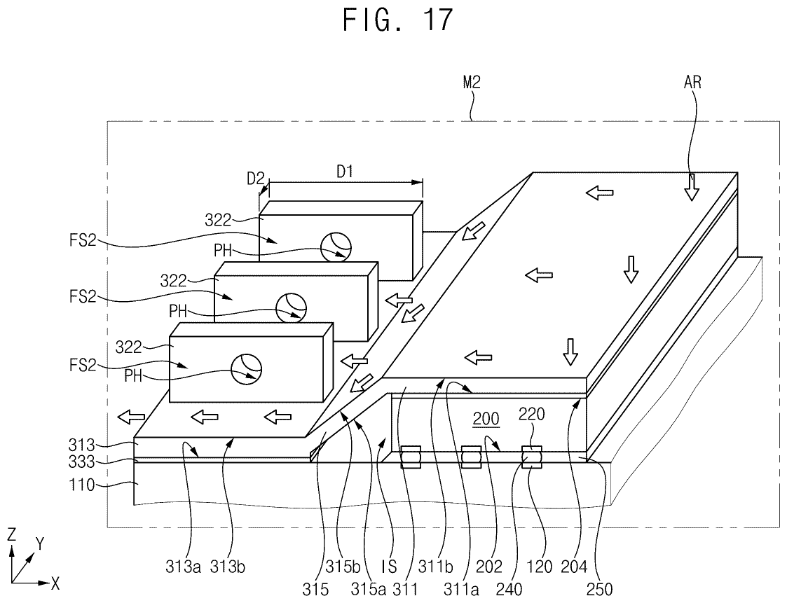

FIG. 15 is a cross-sectional view illustrating a semiconductor package 102 in accordance with some embodiments. FIG. 16 is a plan view illustrating the semiconductor package 102 in FIG. 15. FIG. 17 is a perspective view illustrating portion ‘M2’ in FIG. 15. FIG. 15 is a cross-sectional view taken along line E-E′ in FIG. 16.

The semiconductor package 102 described in FIGS. 15 to 17 is substantially the same as the semiconductor package 100 described in FIGS. 1 to 4 except for a plurality of third heat dissipation fins 322, as such identical components are denoted by the same reference numerals, and repeated descriptions of identical components may be omitted.

Referring to FIGS. 15 to 17, in some embodiments, the semiconductor package 102 may include a package substrate 110, a semiconductor device 200 mounted on the package substrate 110, and a heat dissipation member 300 at least partially covering the package substrate 110 and the semiconductor device 200.

In some embodiments, a plurality of third heat dissipation fins 322 may be provided on the second portion 313 of the heat slug 310. For example, in some embodiments, the plurality of third heat dissipation fins 322 may be provided on the second portion 313 of the heat slug 310 within an edge region ER of the package substrate 110 such that they are arranged along the plurality of side portions S1, S2, S3, S4 of the package substrate 110. For example, in some embodiments, the plurality of third heat dissipation fins 322 may include a metallic material with high thermal conductivity such as copper (Cu), aluminum (Al), or the like.

Each of the plurality of third heat dissipation fins 322 may extend in a first horizontal direction D1 (X direction) toward the semiconductor device 200. For example, in some embodiments, each of the plurality of third heat dissipation fins 322 may extend from a plurality of side portions S1, S2, S3, S4 of the package substrate 110 toward the semiconductor device 200.

Each of the plurality of third heat dissipation fins 322 may be spaced apart from each other in a second horizontal direction D2 (Y direction) perpendicular to the first horizontal direction D1. For example, in some embodiments, each of the plurality of third heat dissipation fins 322 may have a first side surface FS1 and a second side surface FS2 facing each other and extending in the first horizontal direction D1.

In some embodiments, each of the plurality of third heat dissipation fins 322 may have at least one through-hole PH in an interior of the third heat dissipation fin 322 to extend in the first horizontal direction D1. The at least one through-hole PH may penetrate each of the plurality of third heat dissipation fins 322 to extend from the first side surface FS1 to the second side surface FS2.

For example, in some embodiments, the at least one through-hole PH may have a circular shape with a predetermined diameter L1. Alternatively, in some embodiments, the at least one through-hole PH may have a triangular or square shape.

The at least one through-hole PH may be a structure configured to increase the surface area of each of the plurality of third heat dissipation fins 322, which is exposed to an outside of the semiconductor package 102. Thus, each of the plurality of third heat dissipation fins 322 may include the at least one through hole PH to increase the surface area of the semiconductor package 102 exposed to forced convection, thereby improving the thermal performance of the semiconductor package 102. Thus, the plurality of third heat dissipation fins 322 may effectively reduce the temperature of the semiconductor package 102.

Although only one through-hole PH is illustrated in the figures, it will be understood that the number, shape, and arrangement of the through-holes PH are provided as an example, so the present disclosure is not limited thereto.

Each of the plurality of third heat dissipation fins 322 may have a third width W3 extending in the first horizontal direction D1 and a third thickness T3 extending in the second horizontal direction D2. The third width W3 may be greater than the third thickness T3. For example, in some embodiments, each of the plurality of third heat dissipation fins 322 may have a square shape when viewed in a plan view.

Each of the plurality of third heat dissipation fins 322 may extend in a vertical direction (Z direction). Each of the plurality of third heat dissipation fins 322 may have a third fin height FH3 in the vertical direction (Z direction). For example, in some embodiments, the third fin height FH3 may be a height from the upper surface 112 of the package substrate 110 to the upper surface of each of the plurality of third heat dissipation fins 322. The third fin height FH3 of each of the plurality of third heat dissipation fins 322 may be less than the first height H1 of the heat slug 310. Thus, the height in the vertical direction of the semiconductor package 102 may remain constant regardless of the third fin height FH3 of the plurality of third heat dissipation fins 322.

Although only a few of the plurality of third heat dissipation fins 322 are illustrated in the above figures, it will be understood that the number, shape and arrangement of the plurality of third heat dissipation fins 322 are provided as an example, so the present disclosure is not limited thereto.

Hereinafter, another semiconductor package 103 in accordance with some embodiments of the present disclosure will be described.

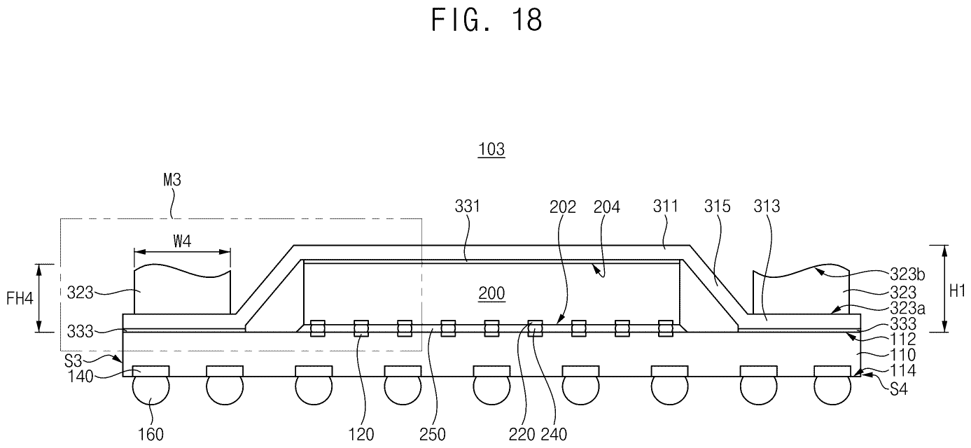

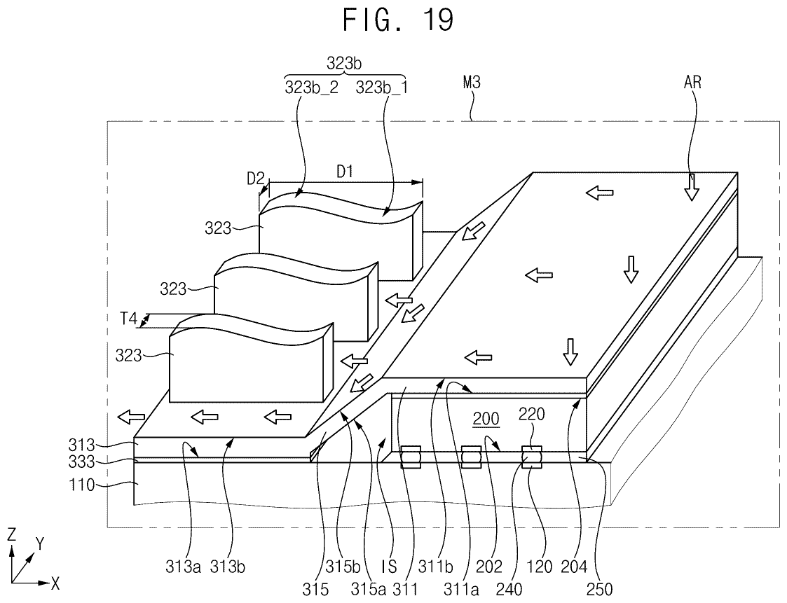

FIG. 18 is a cross-sectional view illustrating the semiconductor package 103 in accordance with some embodiments. FIG. 19 is a perspective view illustrating portion ‘M3’ in FIG. 18.

The semiconductor package 103 described in FIGS. 18 and 19 is substantially the same as the semiconductor package 100 described in FIGS. 1 to 4 except for a plurality of fourth heat dissipation fins 323, as such, identical components are denoted by the same reference numerals and repeated descriptions of identical components may be omitted below.

Referring to FIGS. 18 and 19, in some embodiments, the semiconductor package 103 may include a package substrate 110, a semiconductor device 200 mounted on the package substrate 110, and a heat dissipation member 300 at least partially covering the package substrate 110 and the semiconductor device 200.

A plurality of fourth heat dissipation fins 323 may be provided on the second portion 313 of the heat slug 310. For example, in some embodiments, the plurality of fourth heat dissipation fins 323 may be provided on the second portion 313 of the heat slug 310 within an edge region ER of the package substrate 110 such that the plurality of fourth heat dissipation fins 323 are arranged along the plurality of side portions S1, S2, S3, S4 of the package substrate 110. For example, in some embodiments, the plurality of first heat dissipation fins 323 may include a metallic material with high thermal conductivity such as copper (Cu), aluminum (Al), or the like.

In some embodiments, each of the plurality of fourth heat dissipation fins 323 may have a first surface 323a that is in contact with the second portion 313 of the heat slug 310 and a second surface 323b opposite the first surface 323a to be exposed to an outside of the semiconductor package 103.

The second surface 323b of each of the plurality of fourth heat dissipation fins 323 may have a first region 323b_2 protruding from the package substrate 110 and a second region 323b_1 recessed (or indented) toward the package substrate 110. For example, in some embodiments, each of the plurality of fourth heat dissipation fins 323 may be a wave fin. In some embodiments, each of the plurality of fourth heat dissipation fins 323 may have a wave shape including a plurality of protruding regions (e.g., first region 323b_2) and a plurality of recessed regions (e.g., second region 323b_1) disposed alternately with each other. The wave shape may be a structure configured to increase the surface area of each of the plurality of fourth heat dissipation fins 323. The first region 323b_2 may be or include an upwardly convex surface and the second region 323b_1 may be or include an upwardly concave surface.

Thus, since each of the plurality of fourth heat dissipation fins 323 includes the wave shape, the surface area of the semiconductor package 103 exposed to forced convection may be increased, thereby improving the thermal performance of the semiconductor package 103. Thus, the plurality of fourth heat dissipation fins 323 may effectively reduce the temperature of the semiconductor package 103.

Each of the plurality of fourth heat dissipation fins 323 may extend in the vertical direction (Z direction). Each of the plurality of fourth heat dissipation fins 323 may have a fourth fin height FH4 in the vertical direction (Z direction). For example, in some embodiments, the fourth fin height FH4 may be a height from the upper surface 112 of the package substrate 110 to the first region 323b_2 of the second surface 323b of each of the plurality of fourth heat dissipation fins 323.

The fourth fin height FH4 of each of the plurality of fourth heat dissipation fins 323 may be less than the first height H1 of the heat slug 310. Thus, the height in the vertical direction of the semiconductor package 103 may remain constant regardless of the fourth fin height FH4 of the plurality of fourth heat dissipation fins 323.

Each of the plurality of fourth heat dissipation fins 323 may extend in the first horizontal direction D1 toward the semiconductor device 200. For example, in some embodiments, each of the plurality of fourth heat dissipation fins 323 may extend from a plurality of side portions S1, S2, S3, S4 of the package substrate 110 toward the semiconductor device 200.

Each of the plurality of fourth heat dissipation fins 323 may have a fourth width W4 extending in the first horizontal direction D1 (X direction) and a fourth thickness T4 extending in the second horizontal direction D2 (Y direction). The fourth width W4 may be greater than the fourth thickness T4. For example, in some embodiments, each of the plurality of fourth heat dissipation fins 323 may have a square shape when viewed in a plan view.

While only a few of the plurality of fourth heat dissipation fins 323 are illustrated in the above figures, it will be understood that the number, shape, and arrangement of the plurality of fourth heat dissipation fins 323 are provided as an example, so the present disclosure is not limited thereto.

Hereinafter, another semiconductor package 104 in accordance with some embodiments of the present disclosure will be described.

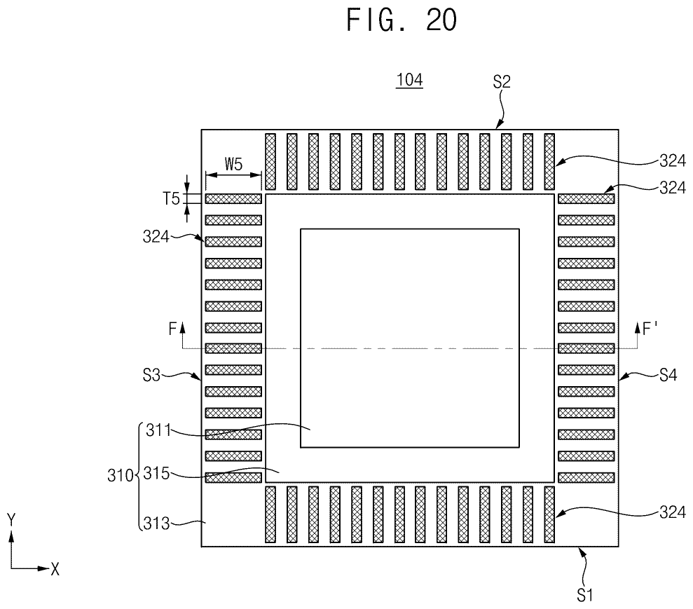

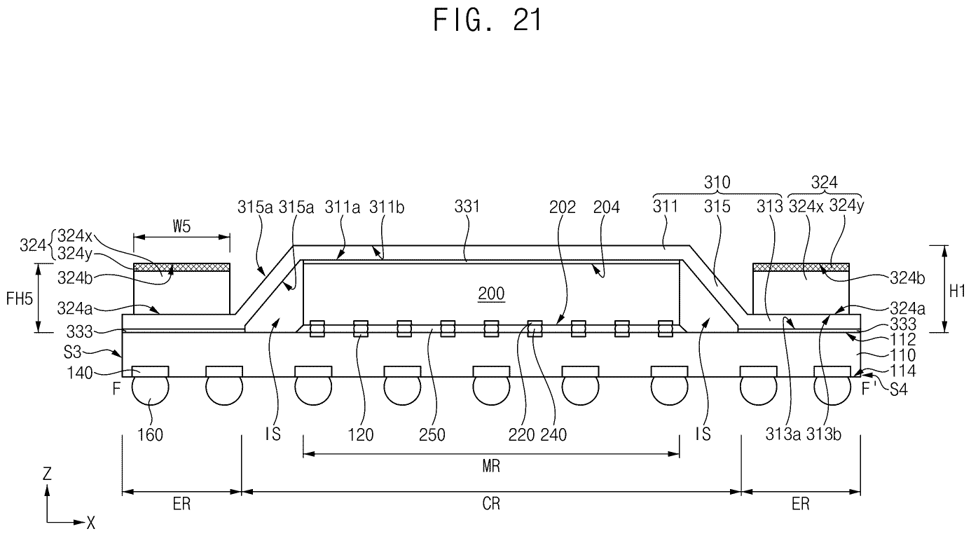

FIG. 20 is a plan view illustrating the semiconductor package 104 in accordance with some embodiments. FIG. 21 is a cross-sectional view taken along the line F-F′ in FIG. 20.

The semiconductor package 104 described in FIGS. 20 and 21 is substantially the same as the semiconductor package 100 described in FIGS. 1 through 4 except for a plurality of fifth heat dissipation fins 324, as such, identical components are denoted by the same reference numerals and repeated descriptions of identical components may be omitted below.

Referring to FIGS. 20 and 21, in some embodiments, the semiconductor package 104 may include a package substrate 110, a semiconductor device 200 mounted on the package substrate 110, and a heat dissipation member 300 at least partially covering the package substrate 110 and the semiconductor device 200.

The plurality of fifth heat dissipation fins 324 may be provided on the second portion 313 of the heat slug 310. For example, in some embodiments, the plurality of fifth heat dissipation fins 324 may be provided on the second portion 313 of the heat slug 310 within the edge region ER of the package substrate 110 such that the plurality of fifth heat dissipation fins 324 are arranged along the plurality of side portions S1, S2, S3, S4 of the package substrate 110.

In some embodiments, each of the plurality of fifth heat dissipation fins 324 may include a body portion 324x stacked on the second portion 313 of the heat slug 31 and including material having a relatively high thermal conductivity. Each of the plurality of fifth heat dissipation fins 324 may further include a coating portion 324y at least partially covering a portion of the body portion 324x and including material having a relatively high emissivity. For example, in some embodiments, the emissivity may be a number that indicates how well a particular object emits (or absorbs) heat by way of radiation. A higher emissivity may increase amount of heat that the particular object transfers by way of radiation. For example, in some embodiments, the body portion 324x may include a metallic material with high thermal conductivity such as copper (Cu), aluminum (Al), or the like. For example, in some embodiments, the coating portion 324y may include a black material. In some embodiments, the coating portion 324y may include a material having an emissivity greater than 0.8. For example, in some embodiments, the coating portion 324y may include a material having an emissivity within the range of 0.8 to 0.9.

Thus, in some embodiments, each of the plurality of fifth heat dissipation fins 324 may have exposed side portions of the body portion 324x with a material having a relatively high thermal conductivity, thereby increasing the surface area of the semiconductor package 104 exposed to forced convection, and improving the thermal performance of the semiconductor package 104. Furthermore, in some embodiments, each of the plurality of fifth heat dissipation fins 324 may include a coating portion 324y with a material having a relatively high emissivity, thereby increasing heat transfer by radiation and improving the thermal performance of the semiconductor package 104. Thus, the plurality of fifth heat dissipation fins 324 may effectively reduce the temperature of the semiconductor package 104.

In some embodiments, each of the plurality of fifth heat dissipation fins 324 may have a first surface 324a that is in contact to the second portion 313 of the heat slug 310 and a second surface 324b that is opposite to the first surface 324a and exposed to an outside of the semiconductor package 104.

Each of the plurality of fifth heat dissipation fins 324 may extend in a vertical direction (Z direction). Each of the plurality of fifth heat dissipation fins 324 may have a fifth fin height FH5 in the vertical direction (Z direction). For example, in some embodiments, the fifth fin height FH5 may be a height from the upper surface 112 of the package substrate 110 to a second surface 324b of each of the plurality of fifth heat dissipation fins 324. The fifth fin height FH5 of each of the plurality of fifth heat dissipation fins 324 may be less than the first height H1 of the heat slug 310. Thus, the height in the vertical direction of the semiconductor package may remain constant regardless of the fifth fin height FH5 of the plurality of fifth heat dissipation fins 324.

Each of the plurality of fifth heat dissipation fins 324 may extend in the first horizontal direction D1 (X direction) toward the semiconductor device 200. For example, in some embodiments, each of the plurality of fifth heat dissipation fins 324 may extend from a plurality of side portions S1, S2, S3, S4 of the package substrate 110 toward the semiconductor device 200. Further, in some embodiments, each of the plurality of fifth heat dissipation fins 324 may be spaced apart from each other in the second horizontal direction D2 (Y direction) perpendicular to the first horizontal direction D1.

Each of the plurality of fifth heat dissipation fins 324 may have a fifth width W5 extending in the first horizontal direction D1 and a fifth thickness T5 extending in the second horizontal direction D2. The fifth width W5 may be greater than the fifth thickness T5. For example, in some embodiments, each of the plurality of fifth heat dissipation fins 324 may have a square shape when viewed in a plan view.

While only a few of the plurality of fifth heat dissipation fins 324 are illustrated in the figures, it will be understood that the number, shape, and arrangement of the plurality of fifth heat dissipation fins 324 are provided as an example, so the present disclosure is not limited thereto.

The semiconductor packages described herein may include semiconductor devices such as logic devices or memory devices. The semiconductor packages described herein may include logic devices such as central processing units (CPUs), main processing units (MPUs), or application processors (APs), or the like, and volatile memory devices such as DRAM devices, HBM devices, or non-volatile memory devices such as flash memory devices, PRAM devices, MRAM devices, ReRAM devices, or the like.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present disclosure. Accordingly, all such modifications are intended to be included within the scope of the embodiments as defined in the claims.

What is claimed is:

1. A semiconductor package, comprising:
a package substrate comprising a mounting region and an edge region at least partially surrounding the mounting region, the edge region being spaced apart from the mounting region in a horizontal direction;
a semiconductor device mounted on the mounting region of the package substrate;
a heat slug provided on the package substrate and the semiconductor device to define an internal space between the package substrate and the heat slug, wherein the semiconductor device is provided within the internal space; and
a plurality of heat dissipation fins provided on the heat slug, each of the plurality of heat dissipation fins arranged along the edge region of the package substrate and extending in a vertical direction,
wherein each of the plurality of heat dissipation fins also extends in the horizontal direction toward the semiconductor device.

2. The semiconductor package of claim 1, wherein each of the plurality of heat dissipation fins has a first length extending in a first horizontal direction toward the semiconductor device, and each of the plurality of heat dissipation fins has a second length extending in a second horizontal direction perpendicular to the first horizontal direction, and
wherein the first length is greater than the second length.

3. The semiconductor package of claim 1, wherein each of the plurality of heat dissipation fins comprises a plurality of heat dissipation sub-fins sequentially disposed from a plurality of side portions of the package substrate toward the semiconductor device.

4. The semiconductor package of claim 1, wherein each of the plurality of heat dissipation fins comprises at least one penetrating hole.

5. The semiconductor package of claim 1, wherein each of the plurality of heat dissipation fins comprises an exposed surface that has a first region protruding from the package substrate and a second region recessed toward the package substrate.

6. The semiconductor package of claim 1, wherein each of the plurality of heat dissipation fins comprises:
a body portion stacked on the heat slug and comprising at least one of copper (Cu) and aluminum (Al); and
a coating portion at least partially covering a portion of the body portion and comprising a material having an emissivity within range of 0.8 to 0.9.

7. The semiconductor package of claim 1, further comprising:
a thermal adhesive member comprising a first adhesive member provided between the semiconductor device and the heat slug and a second adhesive member provided between the package substrate and the heat slug.

8. The semiconductor package of claim 1, wherein the heat slug comprises:
a first portion provided on the semiconductor device;
a second portion provided on the edge region of the package substrate; and
a connecting portion connecting the first portion and the second portion.

9. The semiconductor package of claim 8, wherein a first distance from an upper surface of the package substrate to an upper surface of the first portion of the heat slug defines a first height, and
wherein a second distance from the upper surface of the package substrate to an upper surface of each of the plurality of heat dissipation fins defines a first fin height, and
wherein the first fin height is less than the first height.

10. The semiconductor package of claim 1, wherein the heat slug and the plurality of heat dissipation fins comprise at least one of copper (Cu) and aluminum (Al).

11. A semiconductor package, comprising:
a package substrate comprising a mounting region and an edge region at least partially surrounding the mounting region, the edge region being spaced apart from the mounting region in a horizontal direction;
a semiconductor device mounted on the mounting region of the package substrate; and
a heat dissipation member at least partially covering the package substrate and the semiconductor device,
wherein the heat dissipation member comprises:
a heat slug comprising a first portion provided on the semiconductor device, a second portion provided on the edge region of the package substrate, and a connecting portion connecting the first portion and the second portion; and
a plurality of heat dissipation fins provided on the second portion of the heat slug, each of the plurality of heat dissipation fins arranged along the edge region of the package substrate and extending in a vertical direction.

12. The semiconductor package of claim 11, wherein each of the plurality of heat dissipation fins has a first length extending in a first horizontal direction toward the semiconductor device, and each of the plurality of heat dissipation fins has a second length extending in a second horizontal direction perpendicular to the first horizontal direction, and
wherein the first length is greater than the second length.

13. The semiconductor package of claim 11, wherein each of the plurality of heat dissipation fins comprises a plurality of heat dissipation sub-fins sequentially disposed from a plurality of side portions of the package substrate toward the semiconductor device.

14. The semiconductor package of claim 11, wherein each of plurality of the heat dissipation fins comprises at least one penetrating hole.

15. The semiconductor package of claim 11, wherein each of the plurality of heat dissipation fins comprises an exposed surface that has a first region protruding from the package substrate and a second region recessed toward the package substrate.

16. The semiconductor package of claim 11, wherein each of the plurality of heat dissipation fins comprises:
a body portion stacked on the heat slug and comprising at least one of copper (Cu) and aluminum (al); and
a coating portion at least partially covering a portion of the body portion and comprising a material having an emissivity within range of 0.8 to 0.9.

17. The semiconductor package of claim 11, further comprising:
a thermal adhesive member comprising a first adhesive member provided between the semiconductor device and the heat slug and a second adhesive member provided between the package substrate and the heat slug.

18. The semiconductor package of claim 11, wherein the heat slug and the plurality of heat dissipation fins comprise at least one of copper (Cu) and aluminum (Al).

19. The semiconductor package of claim 11, wherein each of the plurality of heat dissipation fins extends in the horizontal direction toward the semiconductor device.

20. A semiconductor package, comprising:
a package substrate comprising a mounting region and an edge region at least partially surrounding the mounting region, the edge region being spaced apart from the mounting region in a horizontal direction;
a semiconductor device mounted on the mounting region of the package substrate;
a heat slug comprising a first portion provided on the semiconductor device, a second portion provided on the edge region of the package substrate, and a connecting portion connecting the first portion and the second portion;
a plurality of heat dissipation fins provided on the second portion of the heat slug, each of the plurality of heat dissipation fins arranged along the edge region of the package substrate and extending in a vertical direction; and
a thermal adhesive member comprising a first adhesive member provided between the semiconductor device and the first portion of the heat slug and a second adhesive member provided between the package substrate and the second portion of the heat slug,
wherein a first distance from an upper surface of the package substrate to an upper surface of each of the plurality of heat dissipation fins is less than a second distance from the upper surface of the package substrate to an upper surface of the first portion of the heat slug, and
wherein each of the plurality of heat dissipation fins extends in the horizontal direction toward the semiconductor device.
